(19) United States
(12) Patent Application Publication
(10) Pub. No.: US 2011/0315643 A1
(43) Pub. Date: Dec. 29, 2011

(54) LAPTOP TRAY

(76) Inventor: ALBERT MAIMON, Kirkland, WA (US)

(21) Appl. No.: 13/199,778

(22) Filed: Apr. 16, 2010

(51) Int. Cl. H05K 7/00

(52) U.S. Cl. 211/26

(57) ABSTRACT

The new features of the invention not found in most prior art or inventions are the simplicity of the invention, fewer parts, simpler assembly and disassembly, easy storage and portability. Because of the simplicity of design and fewer parts, the invention also costs less than most other inventions that offer a portable work surface for laptop computers.

### CROSS REFERENCE TO RELATED APPLICATIONS

| Pat. No. | Date | Inventor | Title |
|---|---|---|---|
| 5,893,331 | Apr. 13, 1999 | Diletto | Beach and Outdoor Tray |
| | | | Attachments for Lounge Chairs |
| | | | and the Like |
| 6,269,948 | Aug. 7, 2001 | Jackson | Luggage for Nomadic Computing |
| 6,604,472 | Aug. 12, 2003 | McNeil | Laptop Computer Support Table |
| 6,736,073 | May 18, 2004 | Ryburg | Work Surface for Luggage and |
| | | | Luggage Carriers |

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISC APPENDIX

Not applicable

### BACKGROUND OF THE INVENTION

(A) The field of endeavor of the invention pertains to those persons who use laptop computers in mobile/remote situations, rather than in their office or home, and have a wheeled luggage/suitcase with an extendable handle.

The need for the invention is for a sturdy platform to place their laptop computer on when operating in remote locations. Primarily designed for court reporters who usually travel to conference rooms, attorneys and doctors offices. These reporters often use their laptop computers in addition to their stenographic machines, and often there is no room for their laptop computers on the conference table, or there may be no table at all.

Also, many air travelers find themselves in an airport waiting hours for their next flight, and can use this invention to establish a secure platform for their laptop computer affixed to the upright handle of their rolling luggage.

(B) The uniqueness of the invention lies in its simplicity over prior art. This simplicity of design and manufacture also results in lower manufacturing costs and resulting cost savings to the consumer.

Most of the other inventions cited in Section 2 above are cumbersome and have complicated design elements. Many have multiple parts that add to total weight and are cumbersome to store and transport. Others are complicated to assemble. And some do not offer the security and/or stability necessary in operating a laptop computer in portable situations. This invention has only 4 separate parts and assembles or affixes to the upright handles of rolling luggage in a matter of seconds. The invention dismantles easily in seconds, and stores quickly in the user's luggage or in the user's laptop computer carrying case.

In addition, the base of the tray features two cooling holes that help air to circulate and allow heated air from the computer to escape.

### BRIEF SUMMARY OF THE INVENTION

The general idea of the invention is to offer laptop users an easily-assembled, stable platform to place their laptop computers on, in mobile or remote locations.

The invention solves the previously existing problems of prior art by utilizing a more simplified design and manufacturing process that results in an apparatus that is easy to assemble on location, as sturdy as the more complex prior art configurations, is easily disassembled and stored, and costs less than similar inventions.

### Specific Embodiment of the Process, Machine, Manufacture, Composition of Matter, and Improvement Invented

The process of producing the invention is as follows: (Bold numbers refer to parts as depicted in drawings pages 1-6)

1. The main base tray 5 of the invention is made of an aluminum sheet, 13″ long by 12″ wide, preferably 0.090″ or more in thickness. This base sheet 5 is then machined so as to have 2 rounded corners 7 on one of the 13″ sides. Then two 1″ diameter holes 6-B are drilled in the base 5 at 5½″ from the rounded corner 7 13″ side of the base, and 3¼″ from each 11″ side. Then two ½″ diameter holes 6-A are drilled at the 13″ side opposite the round corners 7, centered at ½″ from the top edge and ½″ from each 11″ side. The 13″ side opposite the rounded corners 7 is then bent upwards to a 90-degree angle so as to give the base a 1″ high flange 5-B along the 13″ side opposite the rounded corner 7 side.

2. The next piece of the invention is an aluminum bar 2, 13″ long by 1″ wide, ¼″ thick. Two ½″ diameter holes 8 are drilled, centered midpoint of the 1″ width and 1″ from left and right edges of 13″ length.

3. Two steel headbolts 4, ⅜-16, 1½″ long are inserted through the holes 6-A in the upright flange 5-B of the base tray 5, with the head of the bolt 4 on the base side of the invention, and the length of the headbolt 4 projecting to the rear of the invention. Two ⅜″ steel hex nuts 3, 16×½, are then threaded and tightened onto each headbolt 4 on the opposite side of the flange 5-B.

4. An adjustment knob 1, with a ⅜-16 threaded through-hole, made of nylon or phenolic material, is used to affix the tray to the upright luggage handle by the following assembly process:
a. The base tray 5 is placed on top of the upright luggage with headbolts 4 facing the upright extended handle of the luggage.
b. The 13″ bar 2 is positioned on the opposite side of the extended upright luggage handles.
c. The 13″ bar 2 is positioned so that the holes in the bar align with headbolts 4 of base tray 5.
d. The 13″ bar 2 is then pushed toward the upright handle, causing the headbolts 4 to pass through the holes 8 in the 13″ bar 2.
e. The adjustment knobs 1 are then placed over the headbolts 4, and tightened, which clamps the base tray 5 and bar 2 to the upright luggage handle, so as to provide a secure stable platform.

5. The base 5 and the bar 2 are both anodized or powder coated to protect the finishes and keep the tray in good appearance during its lifetime.

### BRIEF DESCRIPTION OF THE SEVERAL VIEWS OF THE DRAWINGS

FIG. 1 is a top view of the entire invention displaying all parts of the invention.

FIG. 2 is a front view of the 13″ bar, displaying hole placement.

FIG. 3 is a front view of the base tray of the invention, with the upper front view displaying the base tray with the headbolts in place. The lower front view displays the base tray without the headbolts in place to designate the locations of the ½″ holes.

FIG. 4 is a side view of the invention displaying all parts.

FIG. 5 is a top view displaying how the invention mounts on luggage.

FIG. 6 is a front view displaying how the invention mounts on luggage.

FIG. 7 is a side view displaying how the invention mounts on luggage.

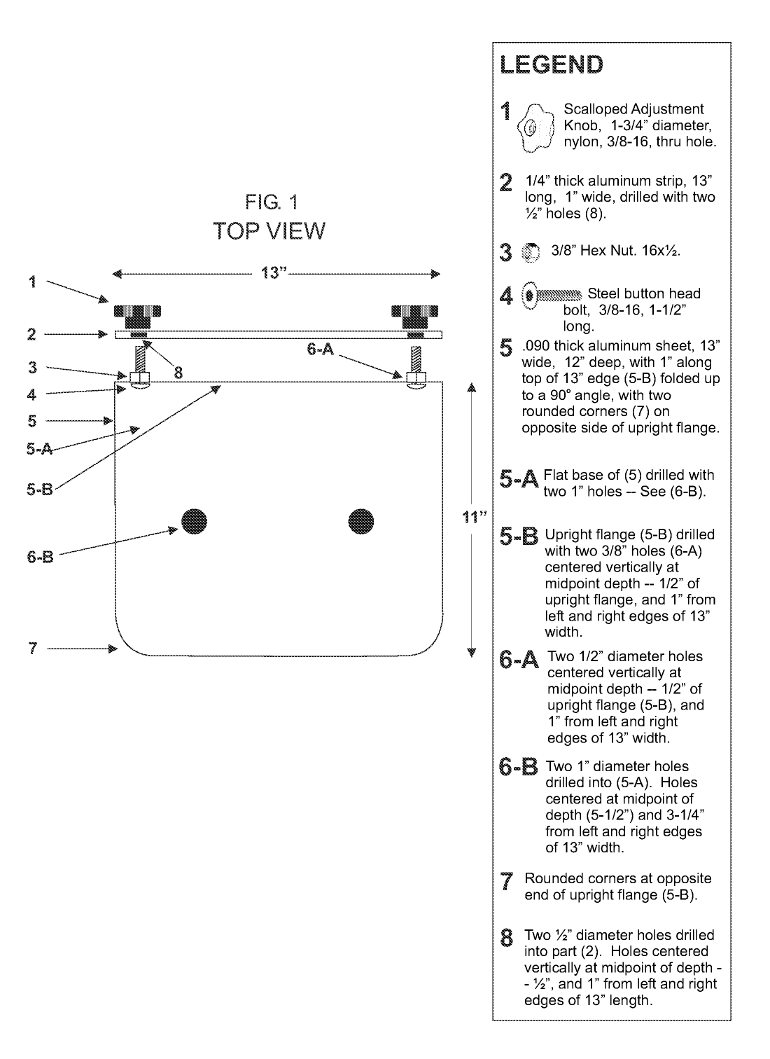

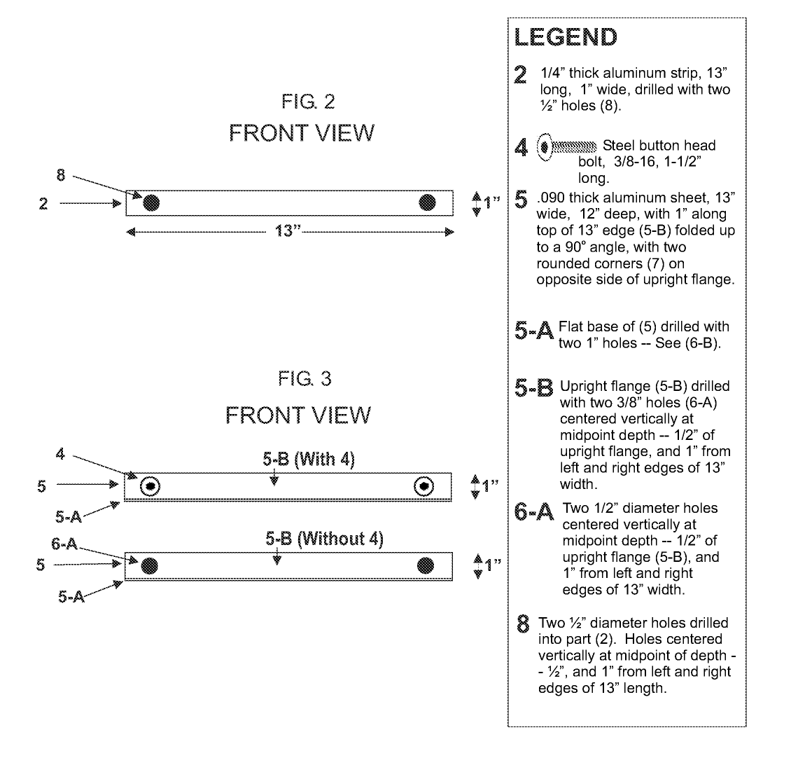

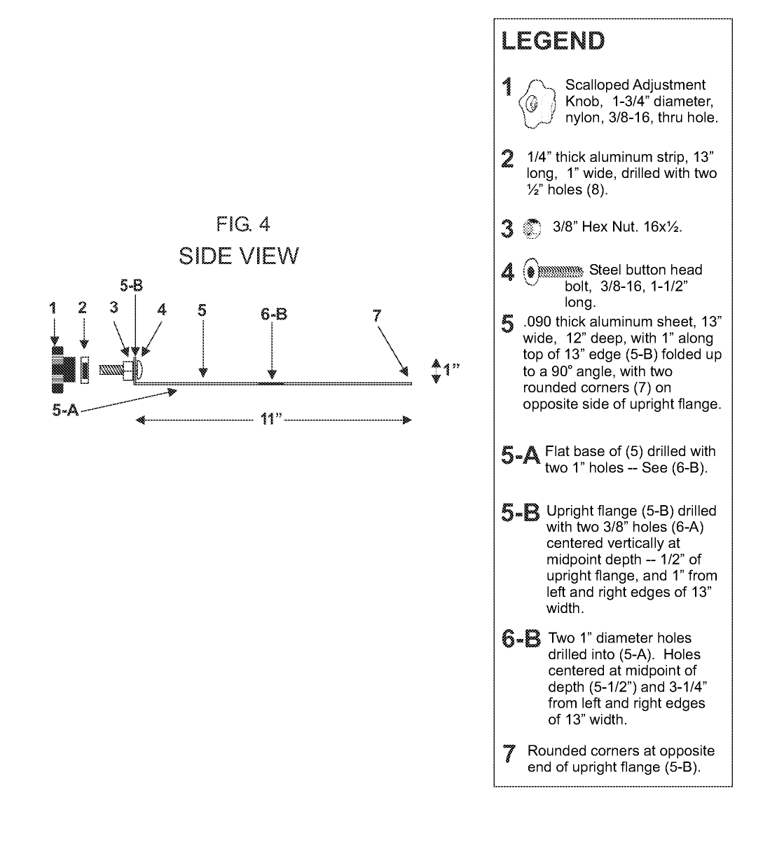

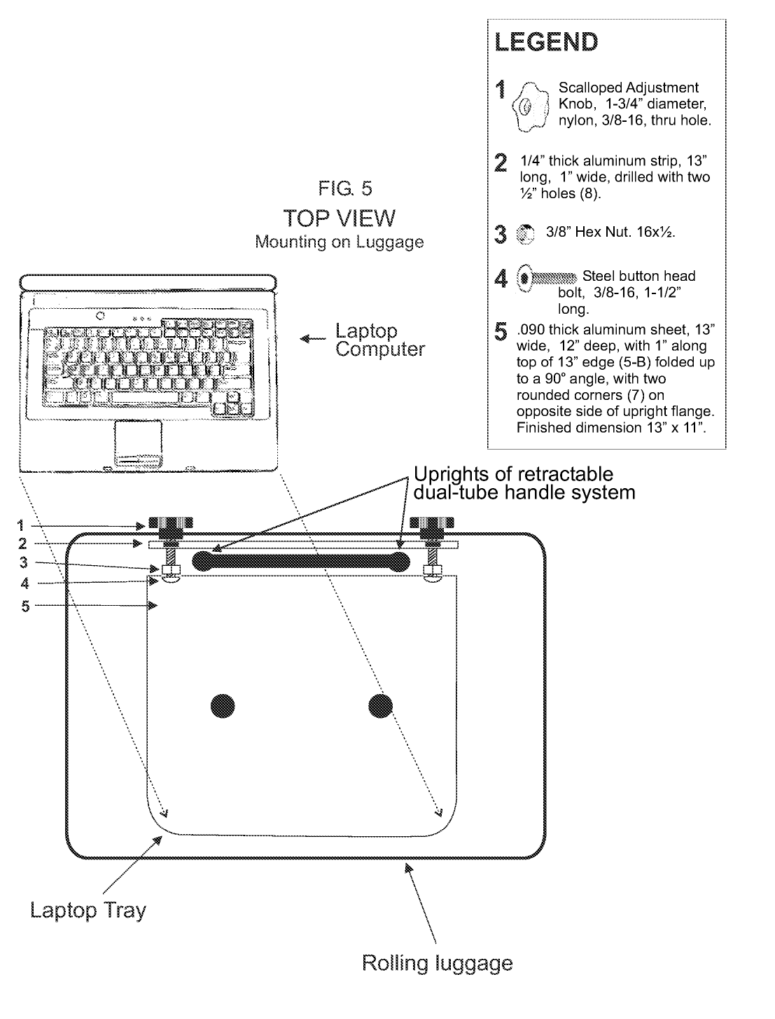

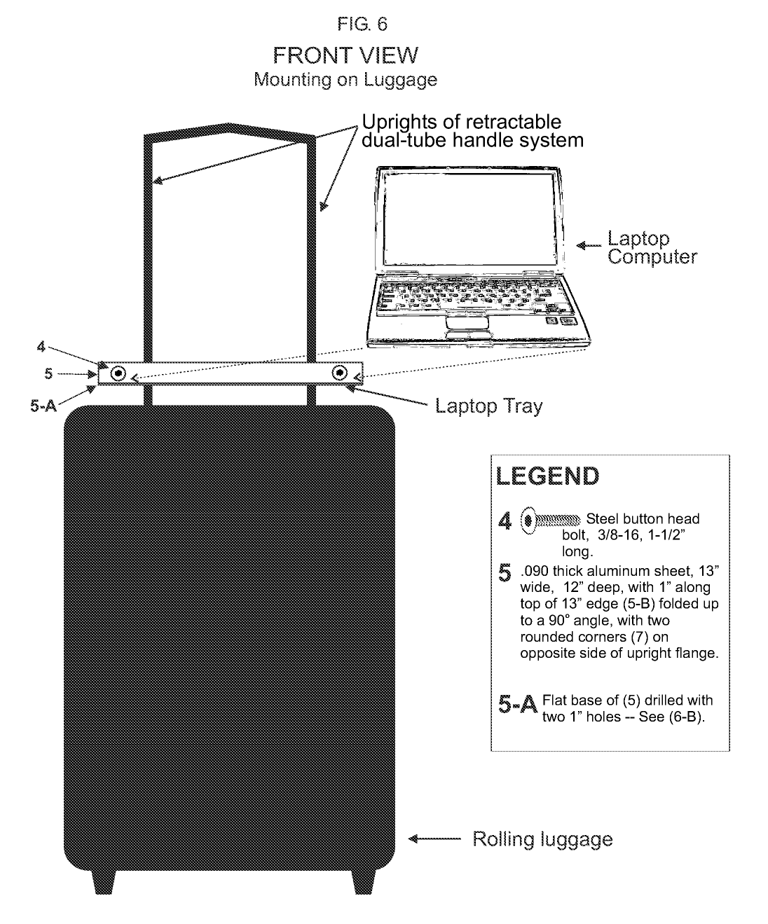

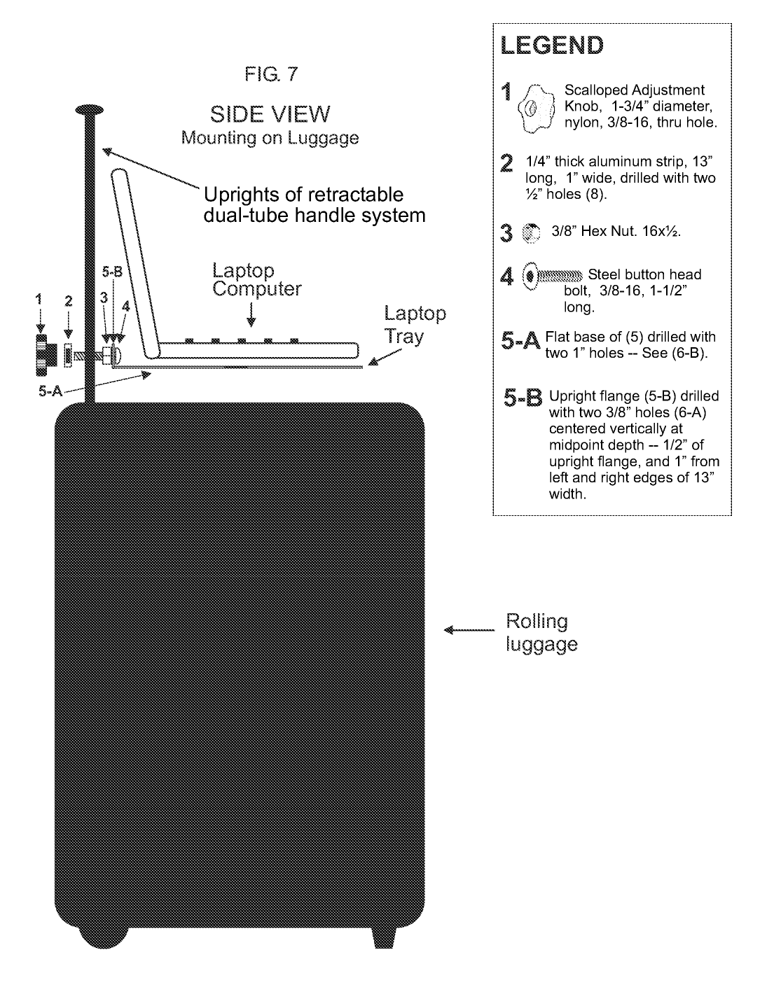

1. A portable tray/support system for laptop computers, comprised of an aluminum base tray of a nominal size to support popular laptop computers, and an aluminum bar, both adapted for use with the extendable handle of wheeled luggage. The tray and bar are clamped together from each side of the upright handle of wheeled luggage by means of tightening adjustment knobs onto bolts that are attached to the base tray.

2. The aluminum base tray as claimed in claim 1 is rectangular in shape, made of aluminum, with a 1″ wide section along the length of the tray bent at a 90-degree angle to create a flange that extends perpendicular from the top surface of the tray.

3. The aluminum base tray as claimed in claim 2 has rounded corners along the length of the tray opposite the flange.

4. The aluminum base tray as claimed in claim 3 has two ½″ diameter holes drilled into the flange at 1″ from each of the width sides, centered at ½″ from top to bottom of the flange.

5. The aluminum base tray as claimed in claim 4 has two 1″ diameter holes drilled into the base at 5½″ from the rounded corner length side, and 3¼″ from the width sides of the tray.

6. The bar as claimed in claim 1 has two ½″ diameter holes drilled at 1″ from each end of the bar, centered at ½″ from top to bottom of the bar.

7. The aluminum base tray as claimed in claim 1 has two 2 headbolts inserted through the ½″ holes as described in claim 5, with the head of the bolts against the inside of the flange, extending through the holes to the backside of the flange.

8. Two hex nuts are mounted and tightened onto the two headbolts on the opposite side of the flange as described in claim 7.
